(19) United States
(12) Patent Application Publication
(10) Pub. No.: US 2026/0090404 A1
(43) Pub. Date: Mar. 26, 2026

(54) SEMICONDUCTOR DEVICE

(71) Applicant: Rohm Co., Ltd., Kyoto-shi (JP)

(72) Inventors: Ryohei UMENO, Kyoto-shi (JP); Tomohira KIKUCHI, Kyoto-shi (JP)

(21) Appl. No.: 19/410,050

(22) Filed: Dec. 5, 2025

Related U.S. Application Data
(63) Continuation of application No. PCT/JP2024/018091, filed on May 16, 2024.

(30) Foreign Application Priority Data
Jun. 12, 2023 (JP) 2023-096057

(51) Int. Cl. H01L 23/495; H01L 23/00; H01L 23/31; H01L 25/065

(52) U.S. Cl. CPC H10W 70/429; H10W 70/411; H10W 90/00; H10W 90/811; H10W 74/114; H10W 90/753; H10W 90/756

(57) ABSTRACT

The semiconductor device includes a semiconductor element, a conductive support member and a sealing resin whose resin side surface faces one side of a first direction. The support member has an outer lead including a root portion extending from the resin side surface, a mount portion on one side of a thickness direction relative to the root portion, and an extended portion connected to the root portion via a bent portion and to the mount portion via another bent portion. The outer lead has a first division including the extended portion, a second division including the root portion and connected to the first division, and a third division including the mount portion and connected to the first division. The first division is greater in second-direction dimension than the second and third divisions. A division boundary between the first and the third divisions is at the extended portion.

### TECHNICAL FIELD

The present disclosure relates to semiconductor devices.

### BACKGROUND ART

Semiconductor devices manufactured using lead frames are known as a type of conventional semiconductor device. An example of such a semiconductor device is described in JP-A-2022-55599. The semiconductor device described in JP-A-2022-55599 comprises a conductive support member, a semiconductor element, and a sealing resin. The conductive support member includes a die pad and a plurality of outer leads. The semiconductor element is mounted on the die pad. The outer leads are exposed from the sealing resin and are electrically connected to the semiconductor element. When manufacturing the semiconductor device, after forming the sealing resin, the dam bars of the lead frame are cut to separate the outer leads from each other. Thereafter, the outer leads are bent. Each outer lead has a greater width at the cut-off portion of the dam bar than other portions of the lead. Such dam bar cut-off portions may produce variant shapes after the bending of the outer leads, such undesired acute profiles.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with the sealing resin being transparent.

FIG. 3 is a front view of the semiconductor device according to the first embodiment of the present disclosure.

FIG. 4 is a left side view of the semiconductor device according to the first embodiment of the present disclosure.

FIG. 5 is a rear view of the semiconductor device according to the first embodiment of the present disclosure.

FIG. 6 is a right side view of the semiconductor device according to the first embodiment of the present disclosure.

FIG. 7 is a cross-sectional view along line VII-VII in FIG. 2.

FIG. 8 is a cross-sectional view along line VIII-VIII in FIG. 2.

FIG. 9 is an enlarged view of parts of the semiconductor device according to the first embodiment of the present disclosure, wherein the upper view shows a part of FIG. 1 and the lower view shows a part of FIG. 3.

FIG. 10 is an enlarged view of parts of the semiconductor device according to the first embodiment of the present disclosure, wherein the upper view shows a part of FIG. 1 and the lower view shows a part of FIG. 3.

FIG. 11 is a plan view showing a process in the manufacture of the semiconductor device according to the first embodiment of the present disclosure.

FIG. 12 is a plan view of a semiconductor device according to a first variation of the first embodiment.

FIG. 13 is a plan view of the semiconductor device according to the first variation of the first embodiment, with the sealing resin shown transparent.

FIG. 14 is a front view of the semiconductor device according to the first variation of the first embodiment.

FIG. 15 is a left side view of the semiconductor device according to the first variation of the first embodiment.

FIG. 16 is a rear view of the semiconductor device according to the first variation of the first embodiment.

FIG. 17 is a right side view of the semiconductor device according to the first variation of the first embodiment.

FIG. 18 is an enlarged view of the semiconductor device according to the first variation of the first embodiment, wherein the upper view shows a part of FIG. 12 and the lower view shows a part of FIG. 14.

FIG. 19 is an enlarged view of the semiconductor device according to the first variation of the first embodiment, wherein the upper view shows a part of FIG. 12 and the lower view shows a part of FIG. 14.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A face A faces (a first side or a second side) in a direction B” is not limited to the situation where the angle of the face A to the direction B is 90° and includes the situation where the face A is inclined with respect to the direction B.

### First Embodiment

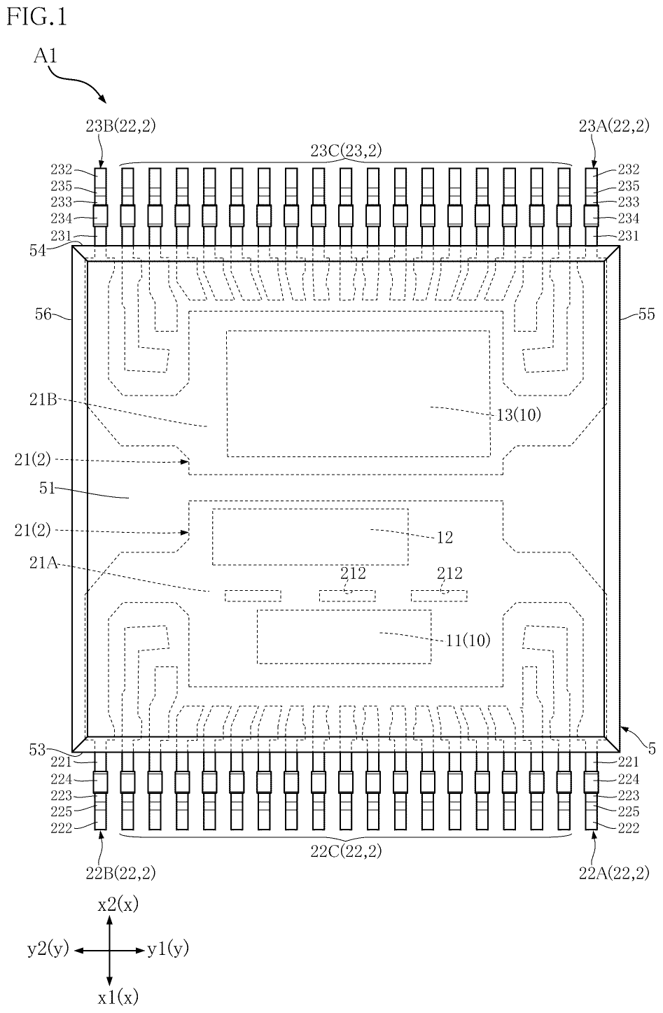

Referring to FIGS. 1 to 10, a semiconductor device A1 according to a first embodiment of the present disclosure will be described. The semiconductor device A1 of this embodiment comprises two semiconductor elements 10, an insulating element 12, a conductive support member 2, a plurality of wires 31 to 34, and a sealing resin 5. The conductive support member 2 includes a die pad section 21, a plurality of first outer leads 22, a plurality of second outer leads 23, a plurality of first inner leads 24, and a plurality of second inner leads 25. The applications of the semiconductor device A1 are not limitative. For instance, the semiconductor device A1 may be surface-mounted on a circuit board of an inverter device used for an electric vehicle or a hybrid vehicle, for example. The packaging type of the semiconductor device A1 shown in the figure is a small outline package (SOP). The packaging type of the semiconductor device A1 is not limited to SOP.

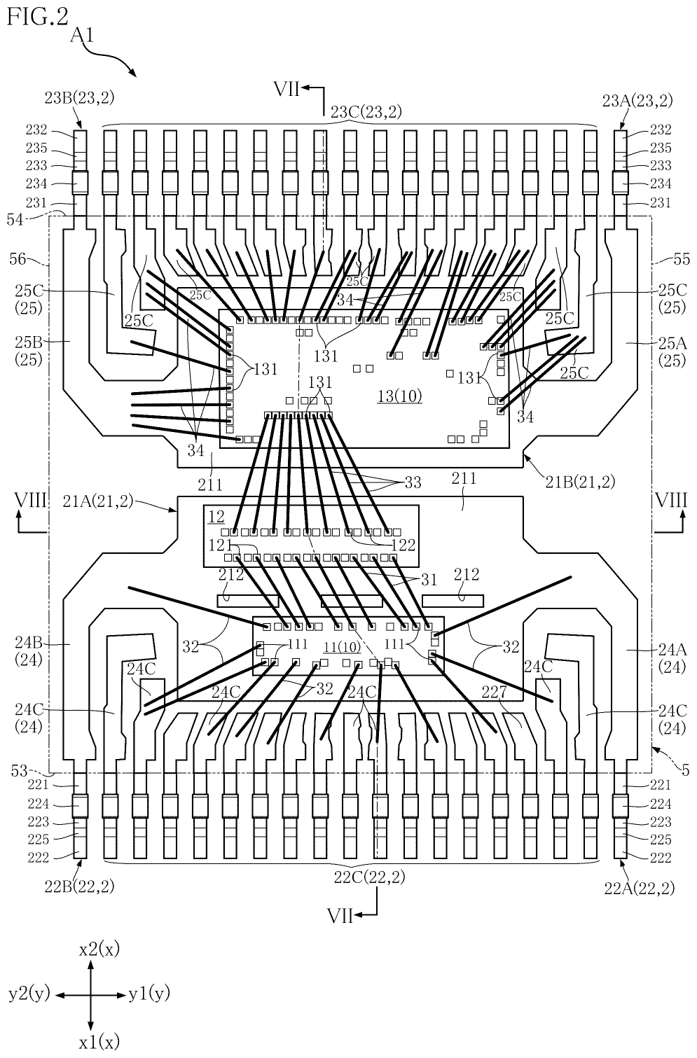

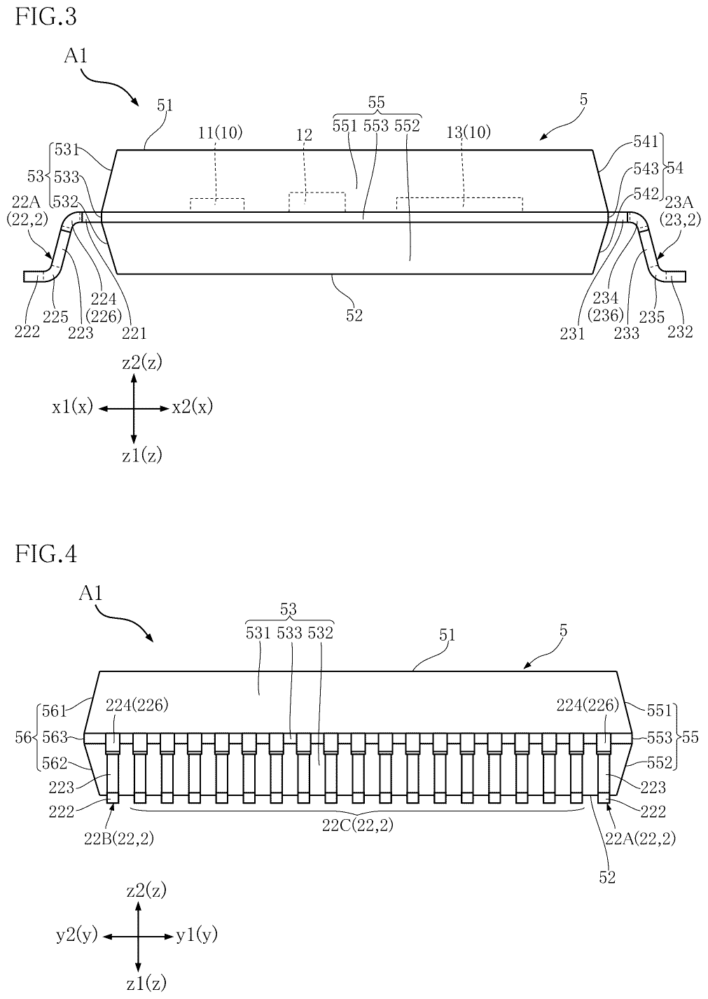

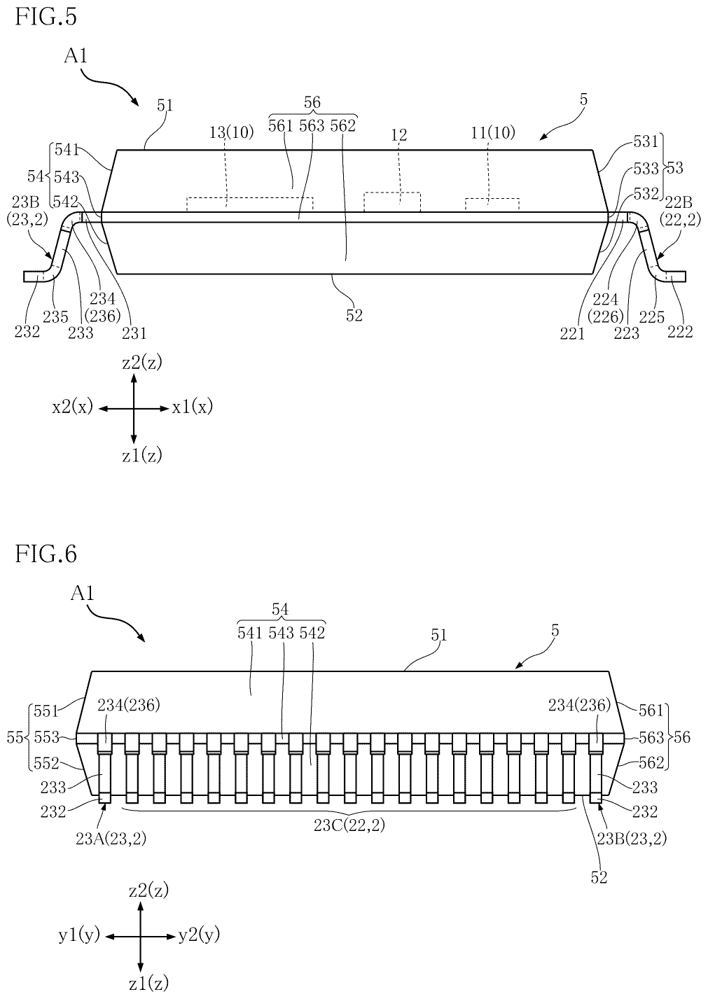

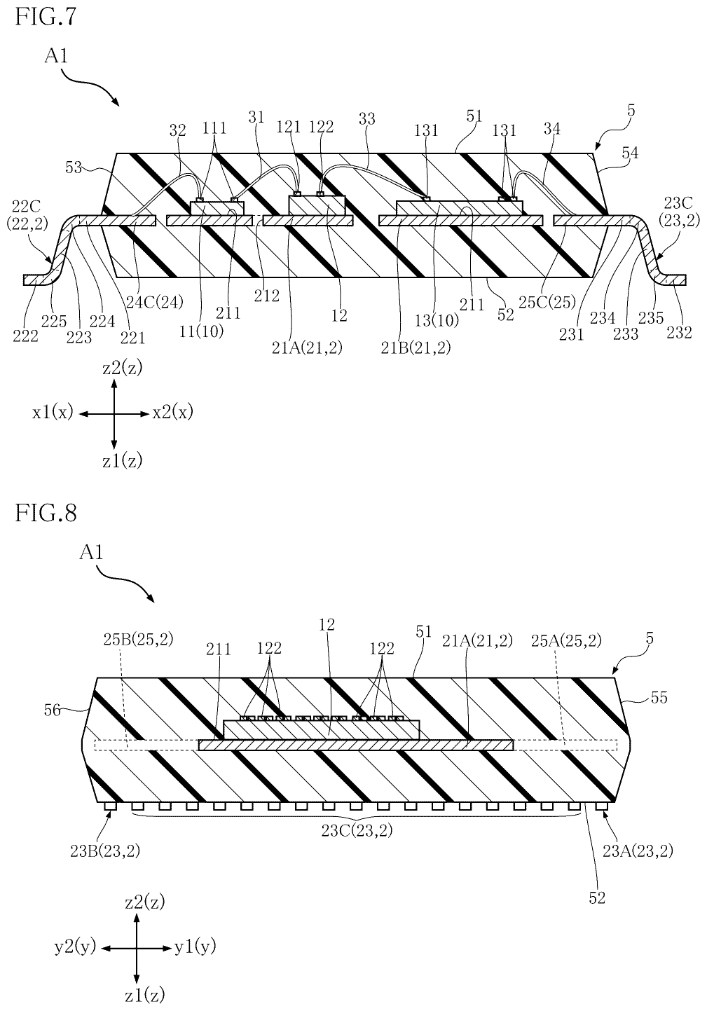

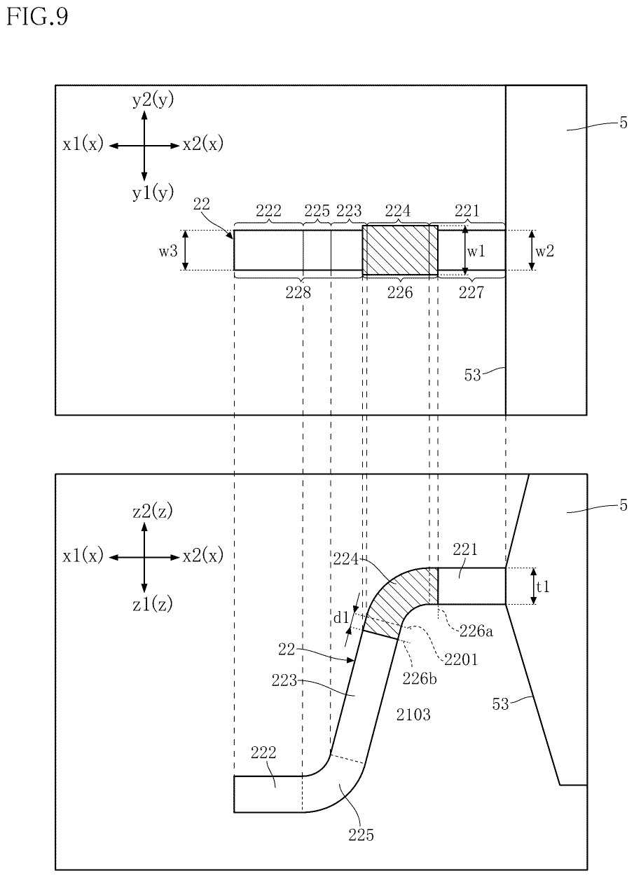

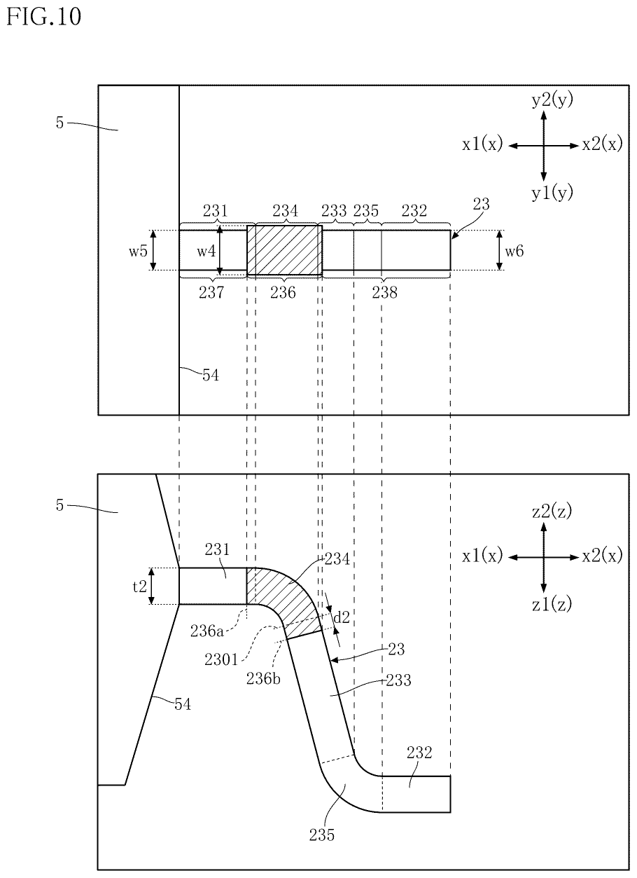

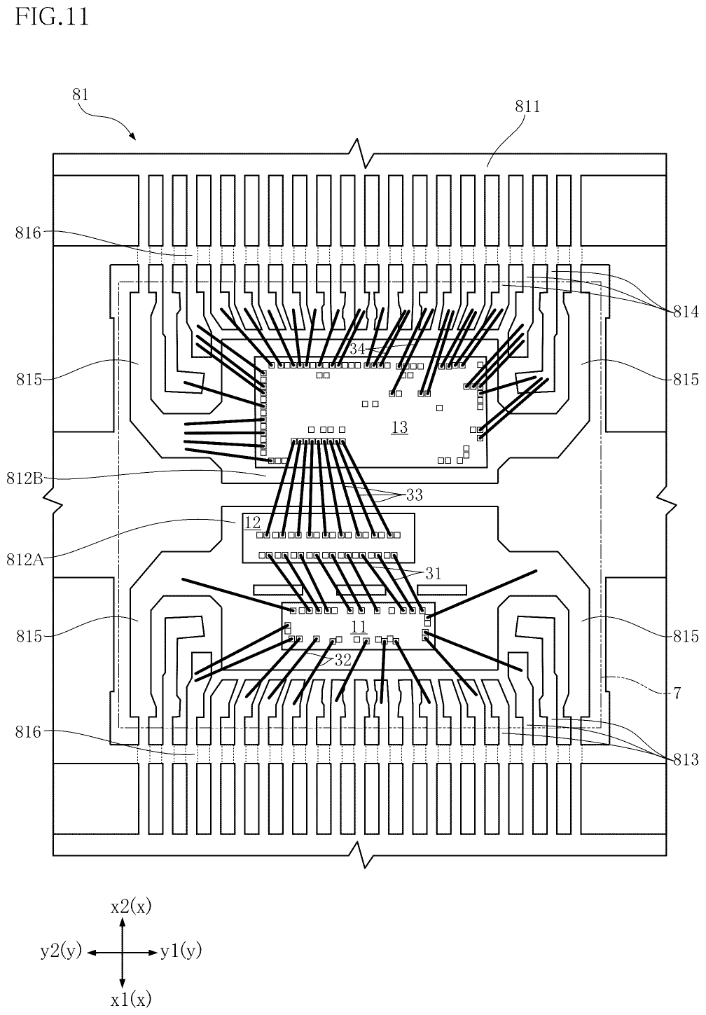

FIGS. 1 and 2 are plan views showing the semiconductor device A1. FIG. 3 is a front view showing the semiconductor device A1. FIG. 4 is a left side view showing the semiconductor device A1. FIG. 5 is a rear view showing the semiconductor device A1. FIG. 6 is a right side view showing the semiconductor device A1. FIG. 7 is a cross-sectional view along line VII-VII in FIG. 2. FIG. 8 is a sectional view along line VIII-VIII in FIG. 2. In FIGS. 9 and 10, the upper part is an enlarged view of FIG. 1 and the lower part is an enlarged view of FIG. 3. In FIG. 2, for ease of understanding, the sealing resin 5 is transparent and indicated by imaginary lines (double dotted lines).

In the description of the semiconductor device A1, the thickness direction of the die pad section 21 (or the conductive support member 2) is referred to as “thickness direction z.” A direction perpendicular to the thickness direction z (the up-down direction in FIG. 1) is referred to as “first direction x.” The direction perpendicular to the thickness direction z and the first direction x (the left-right direction in FIG. 1) is called the “second direction y.” As shown in FIGS. 1 and 2, the semiconductor device A1 is substantially rectangular as viewed in the thickness direction z (in plan view). In FIGS. 1 and 2, the lower side is an example of “one side of the first direction” in this disclosure and is called “the x1 side of the first direction x.” The upper side is an example of the “other or another side of the first direction” in this disclosure and is referred to as the “x2 side of the first direction x.” In FIGS. 1 and 2, the right side is referred to as the “y1 side of the second direction y,” and the left side is referred to as the “y2 side of the second direction y.” In FIGS. 3 to 6, the lower side is an example of “one side in the thickness direction” of the present disclosure and is referred to as “the z1 side in the thickness direction z,” and the upper side is referred to as “the z2 side in the thickness direction z.” In the following description, the z2 side in the thickness direction z is referred to as the upper side, and the z1 side in the thickness direction z is referred to as the lower side. Terms such as “upper,” “lower,” “upper side,” “lower side,” “upper surface,” and “lower surface” indicate the relative positions of components along the thickness direction z and are not necessarily supposed to define the relationship with the direction of gravity.

The two semiconductor elements 10 and the insulating element 12 form the functional core of the semiconductor device A1. As shown in FIG. 2, the two semiconductor elements 10 may include a first semiconductor element 11 and a second semiconductor element 13. In the semiconductor device A1, the first semiconductor element 11, the second semiconductor element 13, and the insulating element 12 are configured as mutually separated elements. As viewed in the thickness direction z, the first semiconductor element 11, the second semiconductor element 13, and the insulating element 12 are rectangular in shape with their long sides extending in the second direction y.

The first semiconductor element 11 is a controller (control element) for a gate driver that drives switching elements such as IGBTs and MOSFETs. As an example, the first semiconductor element 11 includes a circuit for converting control signals inputted from the ECU into PWM control signals, a transmitter circuit for transmitting the PWM control signals to the second semiconductor element 13, and a receiver circuit for receiving electrical signals from the second semiconductor element 13.

The second semiconductor element 13 is a gate driver (driving element) for driving switching elements. The second semiconductor element 13 includes a receiver circuit that receives PWM control signals, a circuit that drives switching elements based on the PWM control signals, and a transmitter circuit that transmits electrical signals to the first semiconductor element 11. Such electrical signal may be output signals from a temperature sensor located near a motor.

The insulating element 12 is configured to transmit various electrical signals including PWM control signals in an insulated state. In the semiconductor device A1, the insulating element 12 shown in the figure is of inductive type. An example of an inductive type insulating element 12 is an isolation transformer. In an isolation transformer, two inductors (coils) are inductively coupled so as to transmit electrical signals in an insulated state. The insulating element 12 includes a substrate made of silicon, and the inductors, made of copper, are formed on the substrate. The inductors include a transmitter-side inductor and a receiver-side inductor, and these inductors may be vertically stacked so as to face each other in the thickness direction z. A dielectric layer made of, for example, silicon dioxide (SiO₂) is disposed between the transmitter-side inductor and the receiver-side inductor. The dielectric layer electrically insulates the transmitter-side inductor from the receiver-side inductor. Alternatively, the insulating element 12 may be of capacitive type. An example of a capacitive insulating element 12 is a capacitor. Further, the insulating element 12 may be a photocoupler.

In the semiconductor device A1, the power voltage for the second semiconductor element 13 is higher than the power voltage for the first semiconductor element 11. Thus, a significant potential difference may occur between the first semiconductor element 11 and the second semiconductor element 13. In view of this, in the semiconductor device A1, a first circuit which includes the first semiconductor element 11 as a component and a second circuit which includes the second semiconductor element 13 as a component are insulated from each other by the insulating element 12. Due to the above-noted potential difference, the potentials of the first and the second circuits are also different. In the semiconductor device A1 shown in the figure, the second circuit has a higher potential than the first circuit. With this situation, the intervening insulating element 12 relays signals to be transmitted reciprocally between the first circuit and the second circuit. In applications of an inverter device for an electric vehicle or a hybrid vehicle, the voltage applied to the ground of the first semiconductor element 11 may be 0 V or so, while the voltage applied to the ground of the second semiconductor element 13 may transiently be 600 V or more.

As shown in FIGS. 2 and 7, a plurality of electrodes 111 are provided on the upper surface of the first semiconductor element 11 (the surface facing the same direction as the mounting surface 211 of the die pad section 21 described later). The electrodes 111 are electrically connected to circuits formed in the first semiconductor element 11. Likewise, a plurality of electrodes 131 are provided on the upper surface of the second semiconductor element 13 (the surface facing in the same direction as the mounting surface 211 described above). The electrodes 131 are electrically connected to circuits formed in the second semiconductor element 13.

As shown in FIGS. 2 and 7, the insulating element 12 is located between the first semiconductor element 11 and the second semiconductor element 13 in the first direction x. A plurality of first electrodes 121 and a plurality of second electrodes 122 are provided on the upper surface of the insulating element 12 (the surface facing in the same direction as the aforementioned mounting surface 211). The first electrodes 121 and the second electrodes 122 are electrically connected to the transmitting-side inductor or the receiving-side inductor. The first electrodes 121 are arranged along the second direction y and are located closer to the first semiconductor element 11 than to the second semiconductor element 13 in the first direction x. The second electrodes 122 are arranged along the second direction y and are located closer to the second semiconductor element 13 than to the first semiconductor element 11 in the first direction x.

The conductive support member 2 constitutes a conduction path in the semiconductor device A1, through which the first semiconductor element 11, the second semiconductor element 13, and the insulating element 12 are electrically connected to the circuit board of the inverter device. The conductive support member 2 is made of an alloy containing copper (Cu), for example. The conductive support member 2 may be formed from a lead frame 81 as described below. The conductive support member 2 has the first semiconductor element 11, the insulating element 12 and the second semiconductor element 13 mounted thereon. As shown in FIGS. 1 and 2, the conductive support member 2 includes a die pad section 21, a plurality of first outer leads 22, a plurality of second outer leads 23, a plurality of first inner leads 24, and a plurality of second inner leads 25. At appropriate locations on the conductive support member 2, a plating layer composed of silver (Ag), nickel (Ni), gold (Au), etc., may be provided as needed.

The die pad section 21 is configured to mount the first semiconductor element 11, the second semiconductor element 13, and the insulating element 12. In this embodiment, the die pad section 21 may include a first die pad 21A and a second die pad 21B. The first die pad 21A and the second die pad 21B are spaced apart from each other in the first direction x. In the illustrated example, the first die pad 21A is located on the x1 side of the first direction x, while the second die pad 21B is located on the x2 side of the first direction x. In the semiconductor device A1, the first semiconductor element 11 and the insulating element 12 are mounted on the first die pad 21A, while the second semiconductor element 13 is mounted on the second die pad 21B.

The die pad section 21 (first die pad 21A and second die pad 21B) is covered with the sealing resin 5. The die pad section 21 (first die pad 21A and second die pad 21B) has a mounting surface 211 facing the z2 side in the thickness direction z. The first semiconductor element 11 and the insulating element 12 are mounted on the mounting surface 211 of the first die pad 21A. The second semiconductor element 13 is mounted on the mounting surface 211 of the second die pad 21B. The first semiconductor element 11, the second semiconductor element 13, and the insulating element 12 are bonded to the mounting surface 211 of the first die pad 21A or the mounting surface 211 of the second die pad 21B via an electroconductive material (e.g., solder or metal paste). The thickness of the first die pad 21A and the second die pad 21B (die pad section 21) is, for example, not less than 100 μm and not more than 300 μm.

As shown in FIGS. 2 and 7, a plurality of through-holes 212 are formed in the first die pad 21A. Each through-hole 212 penetrates the first die pad 21A in the thickness direction z, while also extending along the second direction y. As viewed in the thickness direction z, at least one of the through-holes 212 is located between the first semiconductor element 11 and the insulating element 12. The through-holes 212 are aligned along the second direction y.

By being connected to the circuit board of the inverter device, for example, the first outer leads 22 form a conduction path between the semiconductor device A1 and the circuit board. One or more of the first outer leads 22 are electrically connected to the first semiconductor element 11. As shown in FIGS. 1, 2, and 4, the first outer leads 22 are spaced apart from each other in the second direction y. The first outer leads 22 are exposed so as to extend from the sealing resin 5 (the first resin side surface 53 described later) to the x1 side in the first direction x. As shown in FIGS. 1, 3, and 5, the first outer leads 22 overlap with each other as viewed in the second direction y. The first outer leads 22 include a first lateral outer lead 22A, a first opposite lateral outer lead 22B, and a plurality of first intermediate outer leads 22C. The first lateral outer lead 22A is located at the end of the first outer leads 22 on the y1 side in the second direction y. The first opposite lateral outer lead 22B is located at the other end of the first outer leads 22 on the y2 side in the second direction y. The first intermediate outer leads 22C are disposed between the first lateral outer lead 22A and the first opposite lateral outer lead 22B, as shown in FIGS. 2 and 4.

The first outer leads 22 (first lateral outer lead 22A, first opposite lateral outer lead 22B, and first intermediate outer leads 22C) each include a first root portion 221, a first mount portion 222, a first extended portion 223, a first bent portion 224, and a second bent portion 225.

As shown in FIGS. 1 and 2, the first root portion 221 is located at the root of the first outer lead 22, which is located closer to the sealing resin 5 than the other portions of the first outer lead 22 in the first direction x. Specifically, the first root portion 221 is located closer to the sealing resin 5 than the first mount portion 222 and the first extended portion 223 in the first direction x. The first root portion 221 protrudes from the center of the sealing resin 5 in the thickness direction z, and is located above (on the z2 side of the thickness direction z relative to) the first mount portion 222 in the thickness direction z.

The first mount portion 222 is at the tip of the first outer lead 22. The first mount portion 222 is bonded to the circuit board when the semiconductor device A1 is mounted on the circuit board. As shown in FIGS. 1 and 2, the first mount portion 222 is located opposite from the sealing resin 5 in the first direction x. Thus, the first mount portion 222 is located farther away in the first direction x from the sealing resin 5 than the first root portion 221 and the first extended portion 223. The first mount portion 222 is located below the first root portion 221 in the thickness direction z (on the z1 side of the thickness direction z).

The first extended portion 223 is connected to the first root portion 221 via the first bent portion 224 and is connected to the first mount portion 222 via the second bent portion 225. As viewed in the second direction y, the first extended portion 223 is inclined with respect to the first root portion 221 and the first mount portion 222. As viewed in the second direction y, the first extended portion 223 is inclined with respect to the thickness direction z.

The first bent portion 224 is disposed between the first root portion 221 and the first extended portion 223. The first bent portion 224 is bent downward in the thickness direction z from the first root portion 221. The second bent portion 225 is disposed between the first mount portion 222 and the first extended portion 223. The second bent portion 225 is bent upward in the thickness direction z from the first mount portion 222. The first bent portion 224 and the second bent portion 225 have an arcuate shape as viewed in the second direction y.

The first outer lead 22 includes a first division 226, a second division 227, and a third division 228, as shown in FIG. 9. The first division 226 includes the first extended portion 223. The second division 227 includes the first root portion 221 and is connected to the first division 226. The third division 228 includes the first mount portion 222 and is connected to the first division 226. The dimension w1 of the first division 226 in the second direction y is greater than the dimensions w2 and w3 of the second division 227 and the third division 228 in the second direction y. The first division 226 corresponds in location to the dam bar 816 of a lead frame 81 described later, and has a greater width than other parts as a result of cutting off the dam bar 816. In FIG. 9, hatching is applied to the first division 226.

As understood from FIG. 9, in this embodiment, there is a first division boundary 226a between the first division 226 and the second division 227, and the first division boundary 226a is located at a position overlapping with the first root portion 221. Likewise, between the first division 226 and the third division 228, there is a second division boundary 226b, which is located at a position overlapping with the first extended portion 223. Further, there is a first border 2201 between the first bent portion 224 and the first extended portion 223. As viewed in the second direction y, the distance (first distance d1) between the first border 2201 and the second division boundary 226b is, for example, not less than 0.01 mm and not more than 1.0 mm, preferably not less than 0.01 mm and not more than 0.05 mm. The first distance d1 is not less than 1/20 (one twentieth) of the dimension t1 of the first root portion 221 in the thickness direction and not more than ½ (one half) of the dimension t1 of the first root portion 221. Preferably, the first distance d1 is not less than 1/10 (one tenth) of the dimension t1 of the first root portion 221 and not more than ¼ (one fourth) of the dimension t1.

The first inner leads 24 are covered with the sealing resin 5. The first inner leads 24 extend inward from the first outer leads 22 into the sealing resin 5. The first inner leads 24 include a first lateral inner lead 24A, a first opposite lateral inner lead 24B, and a plurality of first intermediate inner leads 24C.

The first lateral inner lead 24A is connected to the end of the first lateral outer lead 22A on the x2 side of the first direction x. The other end of the first lateral inner lead 24A, opposite from the first lateral outer lead 22A, is connected to the first die pad 21A. The first opposite lateral inner lead 24B is connected to the end of the first opposite lateral outer lead 22B on the x2 side of the first direction x. The other end of the first opposite lateral inner lead 24B, opposite from the first opposite lateral outer lead 22B, is connected to the first die pad 21A. The first intermediate inner leads 24C are connected to the corresponding ends of the first intermediate outer leads 22C on the x2 side of the first direction x, while also extending to locations close to the first die pad 21A.

The second outer leads 23 are bonded to, for example, a circuit board of an inverter device so as to form a conduction path between the semiconductor device A1 and the circuit board. One or more of the second outer leads 23 are electrically connected to the second semiconductor element 13. As shown in FIGS. 1, 2, and 6, the second outer leads 23 are spaced apart from each other in the second direction y. The second outer leads 23 are exposed from the sealing resin 5 (the second resin side surface 54 described later) and extend toward the x2 side in the first direction x. As shown in FIGS. 1, 3, and 5, the second outer leads 23 overlap with each other as viewed in the second direction y. The second outer leads 23 include a second lateral outer lead 23A, a second opposite lateral outer lead 23B, and a plurality of second intermediate outer leads 23C. The second lateral outer lead 23A is located at the end on the y1 side of the second direction y. The second opposite lateral outer lead 23B is located at the other end on the y2 side of the second direction y. The second intermediate outer leads 23C are disposed between the second lateral outer lead 23A and the second opposite lateral outer lead 23B, as shown in FIGS. 2 and 6.

The second outer leads 23 (second lateral outer lead 23A, second opposite lateral outer lead 23B, and second intermediate outer leads 23C) each include a second root portion 231, a second mount portion 232, a second extended portion 233, a third bent portion 234, and a fourth bent portion 235.

The second root portion 231 is at the root of the second outer lead 23. As shown in FIGS. 1 and 2, the second root portion 231 is located closer to the sealing resin 5 than the other portions of the second outer lead 23 in the first direction x. Specifically, the second root portion 231 is located closer to the sealing resin 5 than the second mount portion 232 and the second extended portion 233 in the first direction x. The second root portion 231 protrudes from the center of the sealing resin 5 in the thickness direction z and is located above the second mount portion 232 in the thickness direction z (on the z2 side of the thickness direction z).

The second mount portion 232 is at the tip of the second outer lead 23. The second mount portion 232 is bonded to a circuit board when the semiconductor device A1 is mounted on the circuit board. As shown in FIGS. 1 and 2, the second mount portion 232 is located at the end opposite from the sealing resin 5 in the first direction x. Specifically, the second mount portion 232 is located farther away from the sealing resin 5 in the first direction x than the second root portion 231 and the second extended portion 233. The second mount portion 232 is located below the second root portion 231 in the thickness direction z (on the z1 side of the thickness direction z).

The second extended portion 233 is connected to the second root portion 231 via the third bent portion 234 and connected to the second mount portion 232 via the fourth bent portion 235. As viewed in the second direction y, the second extended portion 233 is inclined with respect to the second root portion 231 and the second root portion 231. As viewed in the second direction y, the second extended portion 233 is inclined with respect to the thickness direction z.

The third bent portion 234 is located between the second root portion 231 and the second extended portion 233. The third bent portion 234 is bent downward in the thickness direction z from the second root portion 231. The fourth bent portion 235 is located between the second mount portion 232 and the second extended portion 233. The fourth bent portion 235 is bent upward in the thickness direction z from the second mount portion 232. As viewed in the second direction y, the third bent portion 234 and the fourth bent portion 235 have an arcuate shape.

As shown in FIG. 10, the second outer lead 23 has a fourth division 236, a fifth division 237, and a sixth division 238. The fourth division 236 includes the second extended portion 233. The fifth division 237 includes the second root portion 231 and is connected to the fourth division 236. The sixth division 238 includes the second mount portion 232 and is connected to the fourth division 236. The dimension w4 of the fourth division 236 in the second direction y is greater than the dimension w5 of the fifth division 237 in the second direction y and also greater than the dimension w6 of the sixth division 238 in the second direction y. The fourth division 236 corresponds in location to the dam bar 816 of the lead frame 81, and has a greater width than other parts as a result of cutting off the dam bar 816. In FIG. 10, hatching is applied to the fourth division 236.

As understood from FIG. 10, in this embodiment, there is a third division boundary 236a between the fourth division 236 and the fifth division 237, and the third division boundary 236a is located at a position overlapping with the second root portion 231. Between the fourth division 236 and the sixth division 238, there is a fourth division boundary 236b, and the fourth division boundary 236b is located at a position overlapping with the second extended portion 233. Between the third bent portion 234 and the second extended portion 233, there is a second border 2301. As viewed in the second direction y, the distance (second distance d2) between the second border 2301 and the fourth division boundary 236b is, for example, not less than 0.01 mm and not more than 1.0 mm, preferably not less than 0.01 mm and not more than 0.05 mm. The second distance d2 is not less than 1/20 (one twentieth) of the dimension t2 of the second root portion 231 in the thickness direction and not more than ½ (one half) of the dimension t2 of the second root portion 231. Preferably, the second distance d2 is not less than 1/10 (one tenth) of the dimension t2 of the second root portion 231 and not more than ¼ (one fourth) of the dimension t2.

The second inner leads 25 are covered by the sealing resin 5. The second inner leads 25 extend inward from the second outer leads 23 into the sealing resin 5. The second inner leads 25 include a second lateral inner lead 25A, a second opposite lateral inner lead 25B, and a plurality of second intermediate inner leads 25C.

The second lateral inner lead 25A is connected to the end of the second lateral outer lead 23A on the x1 side of the first direction x. The second lateral inner lead 25A has an end opposite from the second lateral outer lead 23A, and this end is connected to the second die pad 21B. The second opposite lateral inner lead 25B is connected to the end of the second opposite lateral outer lead 23B on the x1 side of the first direction x. The second opposite lateral inner lead 25B has an end opposite from the second opposite lateral outer lead 23B, and this end is connected to the second die pad 21B. The second intermediate inner leads 25C are connected to the ends of the respective second intermediate outer leads 23C on the x1 side of the first direction x, while also extending to locations close to the second die pad 21B.

The wires 31 to 34, in cooperation with the die pad section 21 (first die pad 21A and second die pad 21B), the first outer leads 22, the second outer leads 23, the first inner leads 24, and the second inner leads 25, constitute a conduction path. Due to the conduction path, the first semiconductor element 11, the second semiconductor element 13, and the insulating element 12 are capable of performing their required functions. The composition of the wires 31 to 34 may include, for example, gold (Au). Alternatively, the composition of the wires may include copper or aluminum (Al).

The wires 31 are connected to first electrodes 121 of the insulating element 12 and to electrodes 111 of the first semiconductor element 11, as shown in FIGS. 2 and 7. Thus, the first semiconductor element 11 and the insulating element 12 are electrically connected to each other. The wires 31 are spaced apart from each other in the second direction y.

The wires 32 are connected to electrodes 111 of the first semiconductor element 11 as shown in FIGS. 2 and 7, while also being connected to the first lateral inner lead 24A, the first opposite lateral inner lead 24B or first intermediate inner leads 24C. Thus, one or more of the first lateral inner lead 24A, the first opposite lateral inner lead 24B and first intermediate inner leads 24C are electrically connected to the first semiconductor element 11.

The wires 33 are connected to the second electrodes 122 of the insulating element 12 and also to electrodes 131 of the second semiconductor element 13, as shown in FIGS. 2 and 7. Thus, the second semiconductor element 13 and the insulating element 12 are electrically connected to each other. The wires 33 are spaced apart from each other in the second direction y. In the semiconductor device A1, the wires 33 bridge between the first die pad 21A and the second die pad 21B.

The wires 34 are connected to the electrodes 131 of the second semiconductor element 13 as shown in FIGS. 2 and 7, while being connected to the second lateral inner lead 25A, the second opposite lateral inner lead 25B or the second intermediate inner leads 25C. Thus, the second lateral inner lead 25A, the second opposite lateral inner lead 25B, and the second intermediate inner leads 25C are electrically connected to the second semiconductor element 13.

The sealing resin 5 covers the first semiconductor element 11, the second semiconductor element 13, the insulating element 12, the die pad section 21 (first die pad 21A and second die pad 21B), the first inner leads 24, and the second inner leads 25, as shown in FIGS. 1 and 2. The sealing resin 5 also covers the wires 31 to 34, as shown in FIG. 7. The sealing resin 5 has electrically insulating. The sealing resin 5 insulates the first die pad 21A and the second die pad 21B from each other. The sealing resin 5 is made of a material containing, for example, a black epoxy resin. As viewed in the thickness direction z, the sealing resin 5 is rectangular.

As shown in FIGS. 3 to 6, the sealing resin 5 has a resin obverse surface 51, a resin reverse surface 52, a first resin side surface 53, a second resin side surface 54, a third resin side surface 55, and a fourth resin side surface 56.

As shown in FIGS. 3 to 6, the resin obverse surface 51 and the resin reverse surface 52 are separated from each other in the thickness direction z. The resin obverse surface 51 and the resin reverse surface 52 face the mutually opposite sides in the thickness direction z. The resin obverse surface 51 faces the z2 side in the thickness direction z, while the resin reverse surface 52 faces the z1 side in the thickness direction z. The resin obverse surface 51 and the resin reverse surface 52 may be flat.

As shown in FIGS. 3 to 6, the first resin side surface 53, the second resin side surface 54, the third resin side surface 55, and the fourth resin side surface 56 are connected to the resin obverse surface 51 and to the resin reverse surface 52, and these side surfaces are disposed between the resin obverse surface 51 and the resin reverse surface 52 in the thickness direction z. As shown in FIGS. 1, 3, and 5, the first resin side surface 53 is located on the x1 side of the first direction x and faces the x1 side of the first direction x. The first outer leads 22 protrude from the first resin side surface 53. The second resin side surface 54 is located on the x2 side of the first direction x and faces the x2 side of the first direction x. The second outer leads 23 protrude from the second resin side surface 54. The third resin side surface 55 and the fourth resin side surface 56 are spaced apart from each other in the second direction y and are each connected to the first resin side surface 53 and to the second resin side surface 54. As shown in FIGS. 1, 4, and 6, the third resin side surface 55 is located on the y1 side of the second direction y and faces the y1 side of the second direction y. The fourth resin side surface 56 is located on the y2 side of the second direction y and faces the y2 side of the second direction y.

As shown in FIGS. 3 to 5, the first resin side surface 53 includes a first upper portion 531, a first lower portion 532, and a first middle portion 533. The first upper portion 531 is connected to the resin obverse surface 51 on the z2 side in the thickness direction z and connected to the first middle portion 533 on the z1 side in the thickness direction z. The first upper portion 531 is inclined with respect to the resin obverse surface 51. The first lower portion 532 is connected to the resin reverse surface 52 on the z1 side of the thickness direction z and connected to the first middle portion 533 on the z2 side of the thickness direction z. The first lower portion 532 is inclined with respect to the resin reverse surface 52. The first middle portion 533 is connected to the first upper portion 531 on the z2 side of the thickness direction z and also connected to the first lower portion 532 on the z1 side of the thickness direction z. The in-plane directions of the first middle portion 533 may include the thickness direction z and the second direction y. As viewed in the thickness direction z, the first middle portion 533 is located outwardly relative to the resin obverse surface 51 and the resin reverse surface 52. The first outer leads 22 are exposed by protruding from the first middle portion 533.

As shown in FIGS. 3, 5, and 6, the second resin side surface 54 includes a second upper portion 541, a second lower portion 542, and a second middle portion 543. The second upper portion 541 is connected to the resin obverse surface 51 on the z2 side in the thickness direction z, and is connected to the second middle portion 543 on the z1 side in the thickness direction z. The second upper portion 541 is inclined with respect to the resin obverse surface 51. The second lower portion 542 is connected to the resin reverse surface 52 on the z1 side of the thickness direction z and also to the second middle portion 543 on the z2 side of the thickness direction z. The second lower portion 542 is inclined with respect to the resin reverse surface 52. The second middle portion 543 is connected to the second upper portion 541 on the z2 side of the thickness direction z and to the second lower portion 542 on the z1 side of the thickness direction z. The in-plane directions of the second middle portion 543 may include the thickness direction z and the second direction y. As viewed in the thickness direction z, the second middle portion 543 is located outwardly relative to the resin obverse surface 51 and the resin reverse surface 52. The second outer leads 23 are exposed by protruding from the second middle portion 543.

As shown in FIGS. 3, 4, and 6, the third resin side surface 55 includes a third upper portion 551, a third lower portion 552, and a third middle portion 553. The third upper portion 551 is connected to the resin obverse surface 51 on the z2 side in the thickness direction z and connected to the third middle portion 553 on the z1 side in the thickness direction z. The third upper portion 551 is inclined with respect to the resin obverse surface 51. The third lower portion 552 is connected to the resin reverse surface 52 on the z1 side of the thickness direction z and to the third middle portion 553 on the z2 side of the thickness direction z. The third lower portion 552 is inclined with respect to the resin reverse surface 52. The third middle portion 553 is connected to the third upper portion 551 on the z2 side of the thickness direction z and to the third lower portion 552 on the z1 side of the thickness direction z. The in-plane directions of the third middle portion 553 may include the thickness direction z and the first direction x. As viewed in the thickness direction z, the third middle portion 553 is located outwardly relative to the resin obverse surface 51 and the resin reverse surface 52.

As shown in FIGS. 4 to 6, the fourth resin side surface 56 includes a fourth upper portion 561, a fourth lower portion 562, and a fourth middle portion 563. The fourth upper portion 561 is connected to the resin obverse surface 51 on the z2 side in the thickness direction z, and connected to the fourth middle portion 563 on the z1 side in the thickness direction z. The fourth upper portion 561 is inclined with respect to the resin obverse surface 51. The fourth lower portion 562 is connected to the resin reverse surface 52 on the z1 side of the thickness direction z and connected to the fourth middle portion 563 on the z2 side of the thickness direction z. The fourth lower portion 562 is inclined with respect to the resin reverse surface 52. The fourth middle portion 563 is connected to the fourth upper portion 561 on the z2 side of the thickness direction z and connected to the fourth lower portion 562 on the z1 side of the thickness direction z. The in-plane directions of the fourth middle portion 563 may include the thickness direction z and the first direction x. As viewed in the thickness direction z, the fourth middle portion 563 is located outwardly relative to the resin obverse surface 51 and the resin reverse surface 52.

In general, a motor driver circuit for an inverter device may be configured as a half-bridge circuit including low-side (low-potential) switching elements and high-side (high-potential) switching elements. In the following, these switching elements are MOSFETs. The reference potential of the sources of the low-side switching elements is ground potential, and the reference potential of the gate drivers that drive the switching elements is also ground potential. On the other hand, the reference potential of the sources of the high-side switching elements corresponds to the potential at the output node of the half-bridge circuit. Similarly, the reference potential of the gate drivers that drive the switching elements corresponds to the potential at the output node of the half-bridge circuit. When the high-side switching elements and the low-side switching elements operate, the potential at the output node varies accordingly. Thus, the reference potential of the gate driver that drives the high-side switching elements also varies. When the high-side switching elements are on, this reference potential may be equal to the voltage applied to the drains of the high-side switching elements (e.g., 600 V or higher). In the semiconductor device A1, the ground of the first semiconductor element 11 and the ground of the second semiconductor element 13 are separated from each other. Thus, when the semiconductor device A1 is used as a gate driver to drive the high-side switching elements, a voltage equal to the voltage applied to the drains of the high-side switching elements may temporarily be applied to the ground of the second semiconductor element 13.

Next, with reference to FIG. 11, a manufacturing method of the semiconductor device A1 will be described. FIG. 11 is a plan view showing a process in manufacturing the semiconductor device. The lead frame 81 is a plate-like material for producing the conductive support member 2. In this embodiment, the base material of the lead frame 81 is copper, for example. The lead frame 81 may be formed by etching a metal plate or by punching a metal plate. The lead frame 81 includes an outer frame 811, a first die pad 812A, a second die pad 812B, a plurality of first leads 813, a plurality of second leads 814, a plurality of support leads 815, and a plurality of dam bars 816.

The first die pad 812A is a portion to produce the first die pad 21A. The second die pad 812B is a portion to produce the second die pad 21B. The first leads 813 are portions to produce the first intermediate outer leads 22C and the first intermediate inner leads 24C. The second leads 814 are portions to produce the second intermediate outer leads 23C and the second intermediate inner leads 25C. The support leads 815 are portions to produce the first lateral outer lead 22A, the first lateral inner lead 24A, the first opposite lateral outer lead 22B, the first opposite lateral inner lead 24B, the second lateral outer lead 23A, the second lateral inner lead 25A, the second opposite lateral outer lead 23B, and the second opposite lateral inner lead 25B. The first leads 813 and the relevant support leads 815 are connected to each other by a dam bar 816. Similarly, the second leads 814 and the relevant support leads 815 are connected to each other by another dam bar 816. After forming the sealing resin 5, the dam bars 816 are partially cut off. As a result, the first leads 813, the second leads 814, and the support leads 815, which were connected to each other by the dam bars 816, are separated from each other. In FIG. 11, the locations for cutting the dam bars 816 are indicated by dotted lines. In each first outer lead 22 and each second outer lead 23, the cut-off portion of the dam bar 816 has a greater width (the dimension in the second direction y) than the other portions of the lead. The cut-off portion in each lead corresponds to the first division 226 or the fourth division 236. After separation, bending is performed on the first outer leads 22 and the second outer leads 23 in a manner such that each first outer lead 22 includes a first root portion 221, a first mount portion 222, a first extended portion 223, a first bent portion 224 and a second bent portion 225, and that each second outer lead 23 includes a second root portion 231, a second mount portion 232, a second extended portion 233, a third bent portion 234 and a fourth bent portion 235.

Next, some of the advantages of the semiconductor device A1 will be explained below.

Each first outer lead 22 includes a first root portion 221, a first mount portion 222, a first extended portion 223, a first bent portion 224, and a second bent portion 225. Further, each first outer lead 22 includes a first division 226, a second division 227, and a third division 228. The first division 226 includes the first extended portion 223. The second division 227 is connected to the first division 226 and includes the first root portion 221. The third division 228 is connected to the first division 226 and includes the first mount portion 222. The dimension w1 of the first division 226 in the second direction y is greater than the dimension w2 of the second division 227 in the second direction y and the dimension w3 of the third division 228 in the second direction y. Between the first division 226 and the third division 228, there is a second division boundary 226b, which is located at a position overlapping with the first extended portion 223. When performing bending processing on each first outer lead 22, the target part of bending deformation to be the first bent portion 224 is subjected to large local tensile forces or compressive forces. If the target part of bending deformation includes portions of dimensionally different cross-sectional shapes, the bending processing results in producing an unduly acute profile of the lead. In this embodiment, as described above, the boundary (second division boundary 226b) between the first division 226, which has a greater width (dimension in the second direction y) and the adjacent third division 228, which has a smaller width (dimension in the second direction y), is located at the first extended portion 223. In other words, the second division boundary 226b is positioned to avoid the first bent portion 224. With this configuration, the first bent portion 224 (first outer lead 22) can have a non-variant, desired profile after the bending.

In the semiconductor device A1, the first division boundary 226a between the first division 226 and the second division 227 is located at the first root portion 221. Further, the division boundaries (the first division boundary 226a and the second division boundary 226b) between the first division 226 and the adjacent second division 227 or the adjacent third division 228 are disposed at locations avoiding the first bent portion 224. With such configurations, it is possible for the first bent portion 224 (first outer lead 22) to have a non-variant, desired profile after the bending.

In this embodiment, the first border 2201 is defined between the first bent portion 224 and the first extended portion 223, and the distance (first distance d1) between the first border 2201 and the second division boundary 226b is 0.01 mm or more and 1.0 mm or less, as viewed in the second direction y. Further, the first distance d1 is not less than 1/20 and not more than ½ of the dimension t1 of the first root portion 221 in the thickness direction z. With this configuration, it is possible to ensure an appropriate first distance d1 between the second division boundary 226b and the first border 2201. This is advantageous to producing a non-variant, desired profile of the first bent portion 224 (first outer lead 22) after the bending.

Each second outer lead 23 includes a second root portion 231, a second mount portion 232, a second extended portion 233, a third bent portion 234, and a fourth bent portion 235. In addition, the second outer lead 23 includes a fourth division 236, a fifth division 237, and a sixth division 238. The fourth division 236 includes the second extended portion 233. The fifth division 237 is connected to the fourth division 236 and includes the second root portion 231. The sixth division 238 is connected to the fourth division 236 and includes the second mount portion 232. The dimension w4 of the fourth division 236 in the second direction y is greater than the dimensions w5 and w6 of the fifth division 237 and the sixth division 238 in the second direction y. The fourth division boundary 236b between the fourth division 236 and the sixth division 238 is located at the second extended portion 233. When the second outer lead 23 is subjected to bending, the target part of bending deformation to be the third bent portion 234 is subjected to large local tensile forces or compressive forces. If the target part of bending deformation includes portions of dimensionally different cross-sectional shapes, the bending processing results in producing a undesired variant shape of the lead, such as an unduly acute profile of the lead. In this embodiment, as described above, the boundary (fourth division boundary 236b) between the fourth division 236, which has a large width (dimension in the second direction y), and the sixth division 238, which is connected thereto and has a small width (dimension in the second direction y), is located at the second extended portion 233. In other words, the fourth division boundary 236b is positioned to avoid the third bent portion 234. With this configuration, the third bent portion 234 (second outer lead 23) can have a non-variant, desired profile after the bending.

In the semiconductor device A1, the third division boundary 236a between the fourth division 236 and the fifth division 237 is located at the second root portion 231. Further, the division boundaries (the third division boundary 236a and the fourth division boundary 236b) between the fourth division 236 and the adjacent fifth division 237 or the adjacent sixth division 238 are disposed at locations avoiding the third bent portion 234. With such configurations, it is possible for the third bent portion 234 (second outer lead 22) to have a non-variant, desired profile after the bending.

In this embodiment, the second border 2301 is defined between the third bent portion 234 and the second extended portion 233, and the distance (second distance d2) between the second border 2301 and the fourth division boundary 236b is 0.01 mm or more and 1.0 mm or less, as viewed in the second direction y. Further, the second distance d2 is not less than 1/20 and not more than ½ of the dimension t2 of the second root portion 231 in the thickness direction z. With this configuration, it is possible to ensure an appropriate second distance d2 between the fourth division boundary 236b and the second border 2301. This is advantageous to producing a non-variant, desired profile of the first bent portion 224 (first outer lead 22) after the bending.

### First Variation of First Embodiment

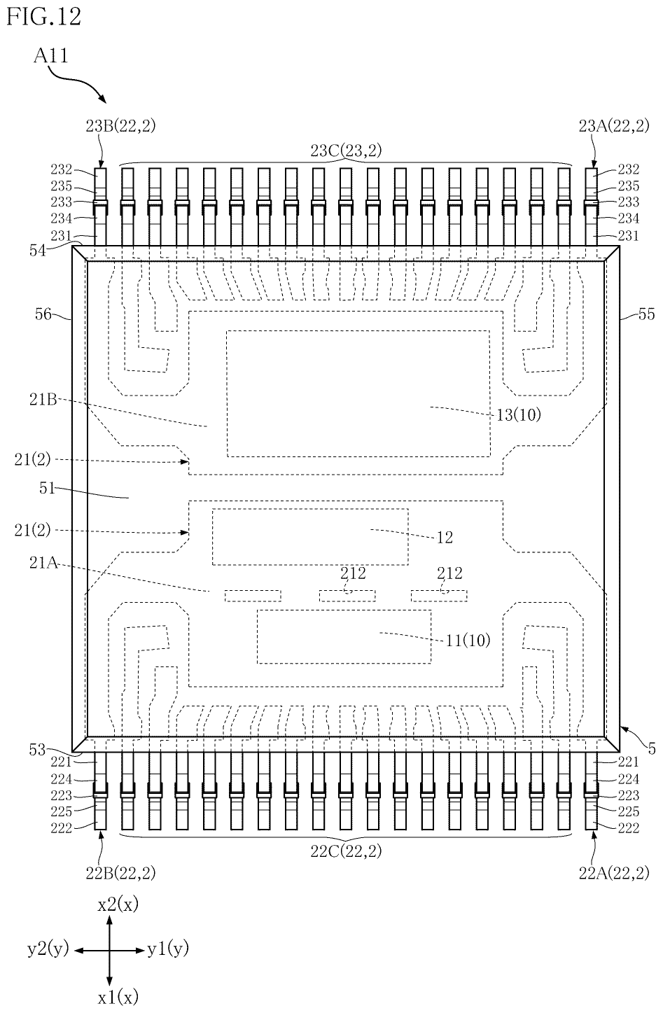

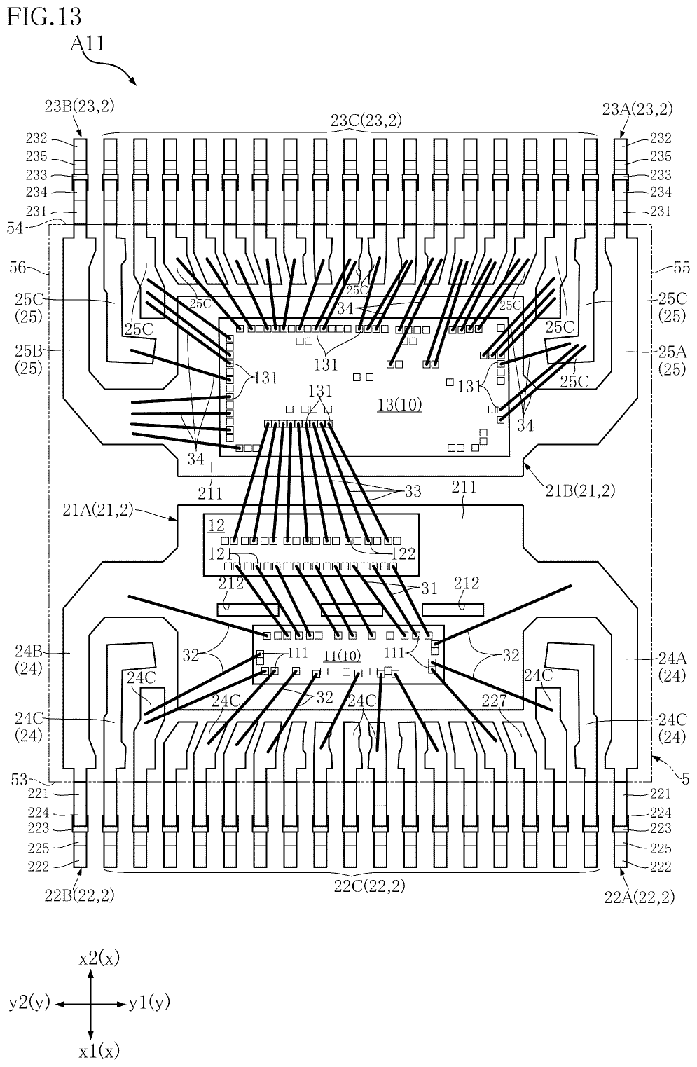

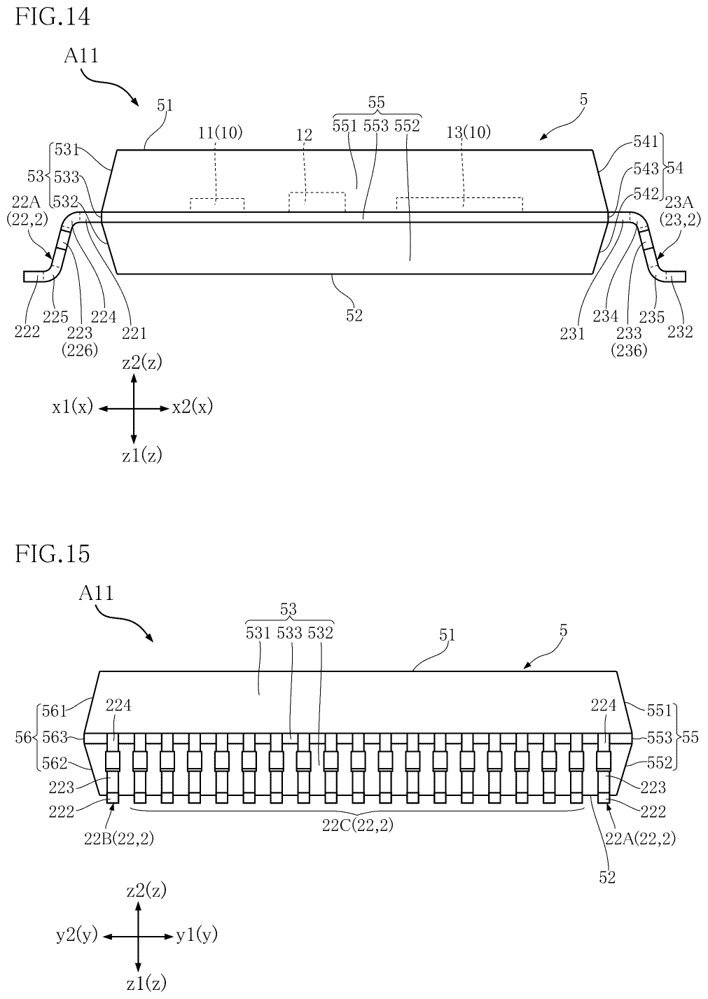

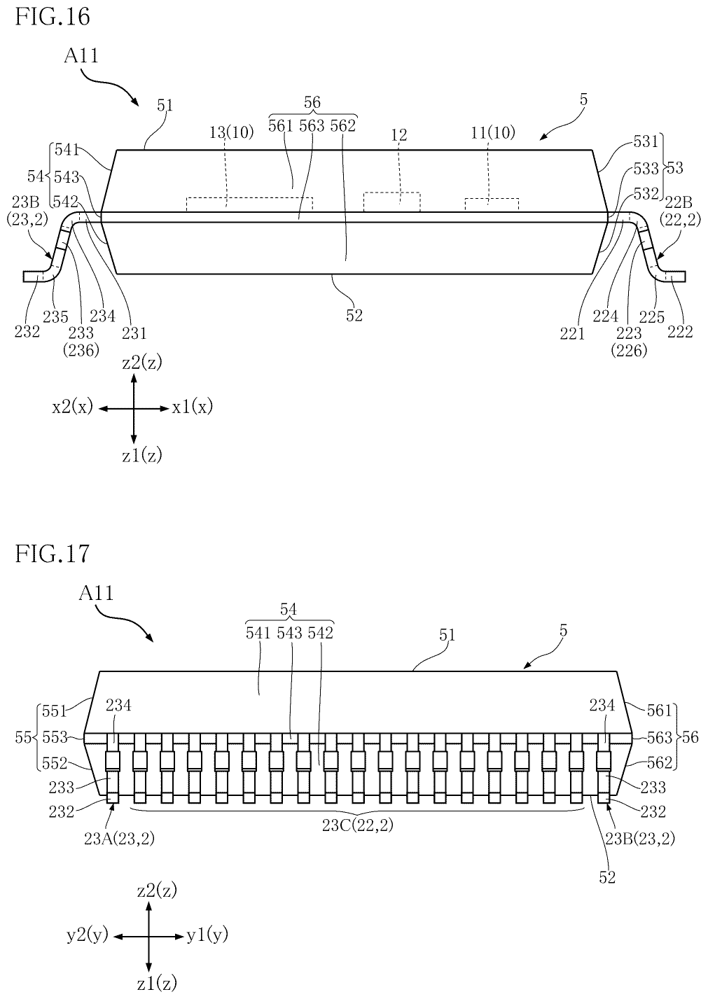

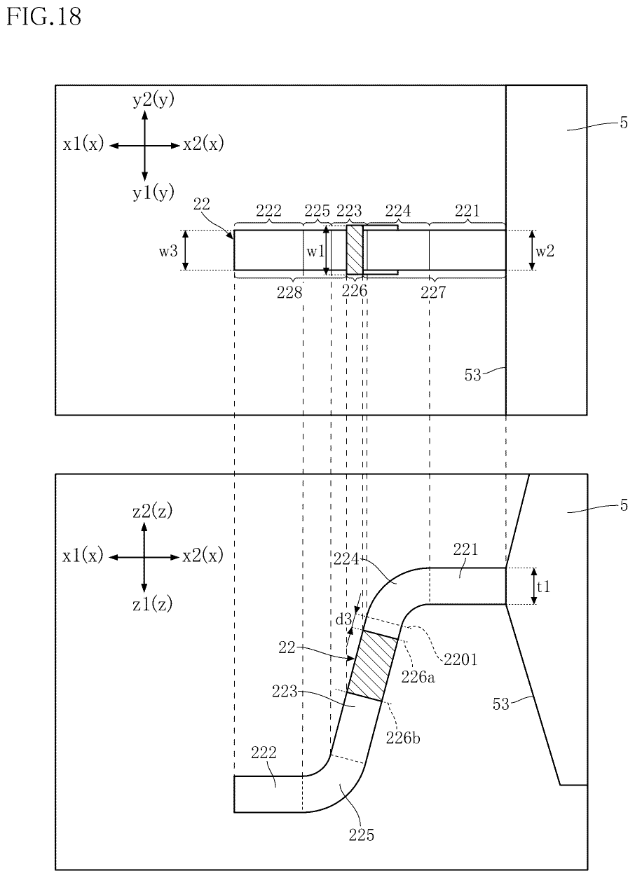

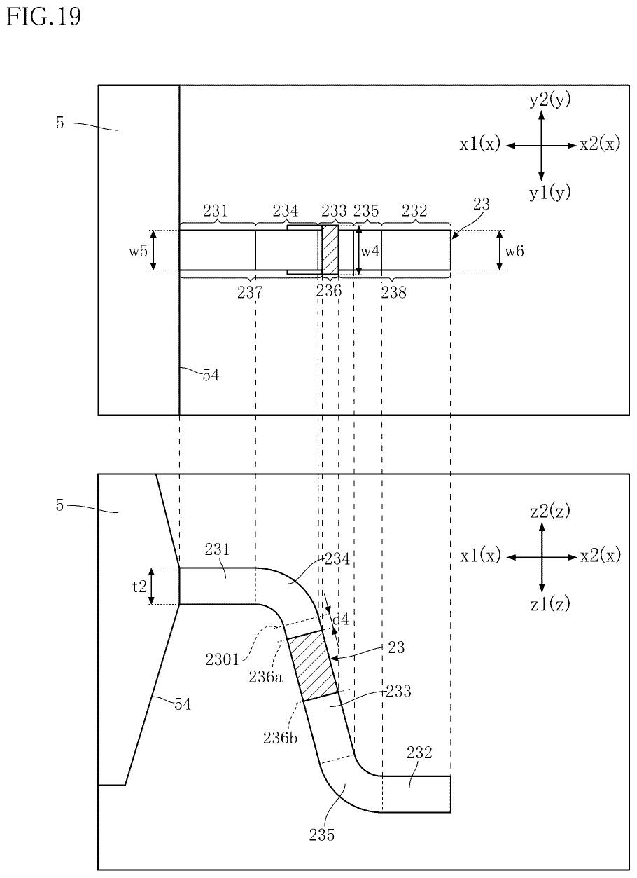

FIGS. 12 to 19 show a semiconductor device according to a first variation of the first embodiment. FIGS. 12 and 13 are plan views of the semiconductor device A11 of this variation. FIG. 14 is a front view of the semiconductor device A11. FIG. 15 is a left side view of the semiconductor device A11. FIG. 16 is a rear view of the semiconductor device A11. FIG. 17 is a right side view of the semiconductor device A11. In each of FIGS. 18 and 19, the upper view shows an enlarged part of FIG. 12, and the lower view shows an enlarged part of FIG. 14. In FIG. 13, for ease of understanding, the sealing resin 5 is depicted as transparent and indicated by imaginary lines (dashed lines). In FIG. 12 and subsequent figures, elements that are the same or similar to those in the semiconductor device A1 of the above embodiment are denoted by the same reference numerals, and their descriptions may be omitted where appropriate.

In the semiconductor device A11 of this variation, the arrangement of the first division 226 in each first outer lead 22 and the arrangement of the fourth division 236 in each second outer lead 23 differ from those in the semiconductor device A1 of the above embodiment.

In this variation, as shown in FIG. 18, the entire first division 226 is provided in the first extended portion 223. As a result, the boundary between the first division 226 and the second division 227 (first division boundary 226a) is located in the first extended portion 223. Similarly, the boundary between the first division 226 and the third division 228 (second division boundary 226b) is located in the first extended portion 223. As viewed in the second direction y, the distance (third distance d3) between the first border 2201, which is between the first bent portion 224 and the first extended portion 223, and the first division boundary 226a is, for example, not less than 0.01 mm and not more than 1.0 mm, and preferably not less than 0.01 mm and not more than 0.05 mm. The third distance d3 is not more than 1/20 and not less than ½ of the dimension t1 of the first root portion 221 in the thickness direction z, and preferably not more than 1/10 and not less than ¼ of the dimension t1. In FIG. 18, hatching is applied to the first division 226.

In this variation, as shown in FIG. 19, the entire fourth division 236 is provided in the second extended portion 233. As a result, the boundary between the fourth division 236 and the fifth division 237 (third division boundary 236a) is located in the second extended portion 233. Similarly, the boundary between the fourth division 236 and the sixth division 238 (fourth division boundary 236b) is located in the second extended portion 233. As viewed in the second direction y, the distance (fourth distance d4) between the second border 2301, which is between the third bent portion 234 and the second extended portion 233, and the third division boundary 236a is, for example, not less than 0.01 mm and not more than 1.0 mm, and preferably not less than 0.01 mm and not more than 0.05 mm. In addition, the fourth distance d4 is not less than 1/20 and not more than ½ of the dimension t2 of the second root portion 231 in the thickness direction z, and preferably not less than 1/10 and not more than ¼ of the dimension t2. In FIG. 19, hatching is applied to the fourth division 236.

In this variation, each first outer lead 22 has a boundary (first division boundary 226a) between the first division 226, which has a greater width (dimension in the second direction y), and the adjacent second division 227, which has a smaller width (dimension in the second direction y). Similarly, there is a boundary (first division boundary 226b) between the first division 226 and the adjacent third division 228 having a smaller width (dimension in the second direction y). These boundaries are located at the first extended portion 223, thereby locationally avoiding the first bent portion 224. By arranging that the first division boundary 226a and the second division boundary 226b, which are defined by portions of different widths (dimension in the second direction y), are disposed at positions avoiding the first bent portion 224, it is possible to produce a non-variant, desired profile of the first bent portion 224 (first outer lead 22) after the bending.

In the semiconductor device A11, the first division boundary 226a and the second division boundary 226b are provided in the first extended portion 223, thereby locationally avoiding the first bent portion 224. This configuration is advantageous to producing a non-variant, desired profile of the first bent portion 224 (first outer lead 22) after the bending.

In this variation, the distance (third distance d3) between the first border 2201, which is between the first bent portion 224 and the first extended portion 223, and the first division boundary 226a is 0.01 mm or more and 1.0 mm or less, as viewed in the second direction y. In addition, the third distance d3 is not less than 1/20 and not more than ½ of the dimension t1 of the first root portion 221 in the thickness direction z. With this configuration, it is possible to secure an appropriate third distance d3 between the first division boundary 226a and the first border 2201. This is advantageous to producing a non-variant, desired profile of the first bent portion 224 (first outer lead 22) after the bending.

In the second outer lead 23 of this variation, there is a boundary (third division boundary 236a) defined between the fourth division 236, which has a greater width (dimension in the second direction y), and the adjacent fifth division 237, which has a smaller width (dimension in the second direction y). Similarly, there is a boundary (fourth division boundary 236b) defined between the fourth division 236 and the adjacent sixth division 238, which has a smaller width (dimension in the second direction y). These boundaries are located in the second extended portion 233, thereby avoiding the third bent portion 234. In this way, the third division boundary 236a and the fourth division boundary 236b, both being defined between adjacent portions having mutually different widths (dimensions in the second direction y), are disposed at locations avoiding the third bent portion 234. This is advantageous to producing a non-variant, desired profile of the third bent portion 234 (second outer lead 23) after the bending.

In the semiconductor device A11, the third division boundary 236a and the fourth division boundary 236b are located in the second extended portion 233, thereby avoiding the third bent portion 234. This is advantageous to producing a non-variant, desired profile of the third bent portion 234 (second outer lead 23) after the bending.

In this variation, the distance (fourth distance d4) between the second border 2301, which is between the third bent portion 234 and the second extended portion 233, and the third division boundary 236a is not less than 0.01 mm and not more than 1.0 mm in the second direction y. The fourth distance d4 is not more than 1/20 and not less than ½ of the dimension t2 of the second root portion 231 in the thickness direction z. With this configuration, it is possible to secure an appropriate fourth distance d4 between the third division boundary 236a and the second border 2301. This is advantageous to producing a non-variant, desired profile of the third bent portion 234 (second outer lead 23) after the bending.

The semiconductor device of the present disclosure is not limited to the above-described embodiments/variations. The configurations of the respective parts of the semiconductor device of the present disclosure may be modified in various ways.

The present disclosure includes the embodiments described in the following clauses.
Clause 1. A semiconductor device comprising:

at least one semiconductor element;

a conductive support member; and

a sealing resin covering the at least one semiconductor element and having a first resin side surface facing one side of a first direction perpendicular to a thickness direction,

wherein the conductive support member comprises at least one first outer lead each including: a first root portion extending in the first direction from the first resin side surface; a first mount portion located on one side of the thickness direction relative to the first root portion; and a first extended portion connected to the first root portion via a first bent portion and connected to the first mount portion via a second bent portion,

the first outer lead comprises: a first division including the first extended portion; a second division including the first root portion and connected to the first division; and a third division including the first mount portion and connected to the first division,

a dimension of the first division in a second direction perpendicular to the thickness direction and the first direction is greater than a dimension of the second division in the second direction and a dimension of the third division in the second direction,

at least either of a first division boundary and a second division boundary is located at the first extended portion, the first division boundary being a boundary between the first division and the second division, the second division boundary being a boundary between the first division and the third division.
Clause 2. The semiconductor device according to clause 1, wherein the first division boundary is located at the first root portion, and the second division boundary is located at the first extended portion.
Clause 3. The semiconductor device according to clause 2, wherein a first border is defined as a boundary between the first bent portion and the first extended portion, and a first distance between the first border and the second division boundary as viewed in the second direction is not smaller than 0.01 mm and not greater than 1.0 mm.
Clause 4. The semiconductor device according to clause 2 or 3, wherein a first border is defined as a boundary between the first bent portion and the first extended portion, and a first distance between the first border and the second division boundary as viewed in the second direction is not smaller than 1/20 of and not greater than ½ of a dimension of the first root portion in the thickness direction.
Clause 5. The semiconductor device according to clause 1, wherein the first division boundary and the second division boundary are located at the first extended portion.
Clause 6. The semiconductor device according to any one of clauses 1-5, wherein the conductive support member comprises a plurality of first outer leads, the plurality of first outer leads are spaced apart from each other in the second direction and arranged to overlap with each other as viewed in the second direction.
Clause 7. The semiconductor device according to any one of clauses 1-6, wherein the sealing resin has a second resin side surface facing another side of the first direction,

the conductive support member comprises at least one second outer lead each including: a second root portion extending from the second resin side surface in the first direction; a second mount portion located on the one side of the thickness direction relative to the second root portion; and a second extended portion connected to the second root portion via a third bent portion and connected to the second mount portion via the fourth bent portion,

the second outer lead comprises: a fourth division including the second extended portion; a fifth division including the second root portion and connected to the fourth division; and a sixth division including the second mount portion and connected to the fourth division,

a dimension of the fourth division in the second direction is greater than a dimension of the fifth division in the second direction and a dimension of the sixth division in the second direction,

at least either of a third division boundary and a fourth division boundary is located at the second extended portion, the third division boundary being a boundary between the fourth division and the fifth division, the fourth division boundary being a boundary between the fourth division and the sixth division.
Clause 8. The semiconductor device according to clause 7, wherein the third division boundary is located at the second root portion, and the fourth division boundary is located at the second extended portion.
Clause 9. The semiconductor device according to clause 8, wherein a second border is defined as a boundary between the third bent portion and the second extended portion, and a second distance between the second border and the fourth division boundary as viewed in the second direction is not smaller than 0.01 mm and not greater than 1.0 mm.
Clause 10. The semiconductor device according to clause 8 or 9, wherein a second border is defined as a boundary between the third bent portion and the second extended portion, and a second distance between the second border and the fourth division boundary as viewed in the second direction is not smaller than 1/20 of and not greater than ½ of a dimension of the second root portion in the thickness direction.
Clause 11. The semiconductor device according to clause 7, wherein the third division boundary and the fourth division boundary are located at the second extended portion.
Clause 12. The semiconductor device according to any one of clauses 7-11, wherein the conductive support member comprises a plurality of second outer leads, the plurality of second outer leads are spaced apart from each other in the second direction and arranged to overlap with each other as viewed in the second direction.
Clause 13. The semiconductor device according to clause 7, wherein the conductive support member comprises a die pad section on which the at least one semiconductor element is mounted.
Clause 14. The semiconductor device according to clause 13, wherein the conductive support member comprises at least one inner lead covered by the sealing resin and extending from the at least one outer lead,

one of the at least one first inner lead is connected to the at least one semiconductor element.
Clause 15. The semiconductor device according to clause 14, wherein the conductive support member comprises at least one second inner lead covered by the sealing resin and extending from the at least one second outer lead,

one of the at least one second inner lead is connected to the at least one semiconductor element.
Clause 16. The semiconductor device according to clause 15, wherein the die pad section comprises a first die pad disposed on the one side of the first direction and a second die pad disposed on the another side of the first direction and spaced apart from the first die pad in the first direction,

the at least one semiconductor element includes a first semiconductor element mounted on the first die pad and a second semiconductor element mounted on the second die pad,

one of the at least one first inner lead is connected to the first semiconductor element,

one of the at least one second inner lead is connected to the second semiconductor element.

1. A semiconductor device comprising:
at least one semiconductor element;
a conductive support member; and
a sealing resin covering the at least one semiconductor element and having a first resin side surface facing one side of a first direction perpendicular to a thickness direction,
wherein the conductive support member comprises at least one first outer lead each including: a first root portion extending in the first direction from the first resin side surface; a first mount portion located on one side of the thickness direction relative to the first root portion; and a first extended portion connected to the first root portion via a first bent portion and connected to the first mount portion via a second bent portion,
the first outer lead comprises: a first division including the first extended portion; a second division including the first root portion and connected to the first division; and a third division including the first mount portion and connected to the first division,
a dimension of the first division in a second direction perpendicular to the thickness direction and the first direction is greater than a dimension of the second division in the second direction and a dimension of the third division in the second direction,
at least either of a first division boundary and a second division boundary is located at the first extended portion, the first division boundary being a boundary between the first division and the second division, the second division boundary being a boundary between the first division and the third division.

2. The semiconductor device according to claim 1, wherein the first division boundary is located at the first root portion, and the second division boundary is located at the first extended portion.

3. The semiconductor device according to claim 2, wherein a first border is defined as a boundary between the first bent portion and the first extended portion, and a first distance between the first border and the second division boundary as viewed in the second direction is not smaller than 0.01 mm and not greater than 1.0 mm.

4. The semiconductor device according to claim 2, wherein a first border is defined as a boundary between the first bent portion and the first extended portion, and a first distance between the first border and the second division boundary as viewed in the second direction is not smaller than 1/20 of and not greater than ½ of a dimension of the first root portion in the thickness direction.

5. The semiconductor device according to claim 1, wherein the first division boundary and the second division boundary are located at the first extended portion.

6. The semiconductor device according to claim 1, wherein the conductive support member comprises a plurality of first outer leads, and the plurality of first outer leads are spaced apart from each other in the second direction and arranged to overlap with each other as viewed in the second direction.

7. The semiconductor device according to claim 1, wherein the sealing resin has a second resin side surface facing another side of the first direction,
the conductive support member comprises at least one second outer lead each including: a second root portion extending from the second resin side surface in the first direction; a second mount portion located on the one side of the thickness direction relative to the second root portion; and a second extended portion connected to the second root portion via a third bent portion and connected to the second mount portion via the fourth bent portion,
the second outer lead comprises: a fourth division including the second extended portion; a fifth division including the second root portion and connected to the fourth division; and a sixth division including the second mount portion and connected to the fourth division,
a dimension of the fourth division in the second direction is greater than a dimension of the fifth division in the second direction and a dimension of the sixth division in the second direction,
at least either of a third division boundary and a fourth division boundary is located at the second extended portion, the third division boundary being a boundary between the fourth division and the fifth division, the fourth division boundary being a boundary between the fourth division and the sixth division.

8. The semiconductor device according to claim 7, wherein the third division boundary is located at the second root portion, and the fourth division boundary is located at the second extended portion.

9. The semiconductor device according to claim 8, wherein a second border is defined as a boundary between the third bent portion and the second extended portion, and a second distance between the second border and the fourth division boundary as viewed in the second direction is not smaller than 0.01 mm and not greater than 1.0 mm.

10. The semiconductor device according to claim 8, wherein a second border is defined as a boundary between the third bent portion and the second extended portion, and a second distance between the second border and the fourth division boundary as viewed in the second direction is not smaller than 1/20 of and not greater than ½ of a dimension of the second root portion in the thickness direction.

11. The semiconductor device according to claim 7, wherein the third division boundary and the fourth division boundary are located at the second extended portion.

12. The semiconductor device according to claim 7, wherein the conductive support member comprises a plurality of second outer leads, and the plurality of second outer leads are spaced apart from each other in the second direction and arranged to overlap with each other as viewed in the second direction.

13. The semiconductor device according to claim 7, wherein the conductive support member comprises a die pad section on which the at least one semiconductor element is mounted.

14. The semiconductor device according to claim 13, wherein the conductive support member comprises at least one inner lead covered by the sealing resin and extending from the at least one outer lead, and one of the at least one first inner lead is connected to the at least one semiconductor element.

15. The semiconductor device according to claim 14, wherein the conductive support member comprises at least one second inner lead covered by the sealing resin and extending from the at least one second outer lead, and one of the at least one second inner lead is connected to the at least one semiconductor element.

16. The semiconductor device according to claim 15, wherein the die pad section comprises a first die pad disposed on the one side of the first direction and a second die pad disposed on the another side of the first direction and spaced apart from the first die pad in the first direction,
the at least one semiconductor element includes a first semiconductor element mounted on the first die pad and a second semiconductor element mounted on the second die pad,
one of the at least one first inner lead is connected to the first semiconductor element,
one of the at least one second inner lead is connected to the second semiconductor element.
